(19) United States
(12) Patent Application Publication
(10) Pub. No.: US 2025/0075306 A1
(43) Pub. Date: Mar. 6, 2025

(54) MASK FRAME AND MASK ASSEMBLY HAVING THE SAME

(71) Applicant: Samsung Display Co., LTD., Yongin-si (KR)

(72) Inventors: Kook Chol PARK, Yongin-si (KR); Il Seob YOON, Yongin-si (KR); Seong Woo JEONG, Yongin-si (KR)

(73) Assignee: Samsung Display Co., LTD., Yongin-si (KR)

(21) Appl. No.: 18/733,178

(22) Filed: Jun. 4, 2024

(30) Foreign Application Priority Data
Aug. 28, 2023 (KR) 10-2023-0113141

(51) Int. Cl. C23C 14/04

(52) U.S. Cl. CPC C23C 14/042

(57) ABSTRACT

A mask frame includes: a frame main body that supports a mask; an insulating layer that blocks energy from being transmitted to the frame main body, and an absorption layer that absorbs energy from external light, wherein the insulating layer is disposed between a first surface of the frame main body and the absorption layer.

### CROSS-REFERENCE TO RELATED APPLICATION(S)

This application claims priority to and benefits of Korean Patent Application No. 10-2023-0113141 under 35 U.S.C. § 119, filed on Aug. 28, 2023, in the Korean Intellectual Property Office, the entire contents of which are incorporated herein by reference.

### BACKGROUND

### 1. Technical Field

Embodiments relate to a mask frame and a mask assembly having the mask frame.

### 2. Description of the Related Art

A display panel includes pixels. Each pixel includes a driving element such as a transistor and a display element such as an organic light emitting element. The display element may be formed by stacking an electrode and various functional layers on a substrate.

The functional layers forming the display element are patterned and provided using a mask having an open area defined to penetrate. For example, shapes of the patterned functional layers may be controlled according to a shape of the open area of the mask. The mask and mask frame for manufacturing the display element may be cleaned after the deposition process. As the resolution of the display element increases, dry cleaning is preferred over wet cleaning for cleaning the mask and the mask frame.

### SUMMARY

Embodiments provide a mask frame and a mask assembly having the mask frame that rapidly and effectively removes residual organic materials during a cleaning process.

However, embodiments of the disclosure are not limited to those set forth herein. The above and other embodiments will become more apparent to one of ordinary skill in the art to which the disclosure pertains by referencing the detailed description of the disclosure given below.

In an embodiment, a mask frame may include: a frame main body that supports a mask; an insulating layer that blocks energy from being transmitted to the frame main body; and an absorption layer that absorbs energy from external light, wherein the insulating layer may be disposed between a first surface of the frame main body and the absorption layer.

The frame main body may include a frame opening defined by an inner side surface perpendicular to the first surface, and the mask may be disposed in the frame opening.

The insulating layer may include a ceramic material.

A thickness of the absorption layer may be thinner than a thickness of the frame main body.

The absorption layer may include a metallic material.

The insulating layer may be disposed between the absorption layer and the inner side surface defining the frame opening.

The insulating layer may be disposed between an outer side surface of the frame main body and the absorption layer.

In an embodiment, a mask assembly may include: a mask that forms a functional layer of a display device by a deposition process; and a mask frame that supports the mask, wherein the mask frame may include a frame main body that supports the mask; a first insulating layer that blocks energy from being transmitted to the frame main body; and a first absorption layer that absorbs energy from external light, wherein the first insulating layer may be disposed between a first surface of the frame main body and the first absorption layer.

The mask assembly may further include a second insulating layer that blocks energy from being transmitted to the mask; and a second absorption layer that absorbs energy from the external light. The second insulating layer may be disposed between the mask and the second absorption layer.

The frame main body may include a frame opening defined by an inner side surface perpendicular to the first surface, and the mask may be disposed in the frame opening.

The first insulating layer may include a ceramic material.

A thickness of the first absorption layer may be thinner than a thickness of the frame main body.

The first absorption layer may include a metallic material.

A thickness of the second absorption layer may be thinner than a thickness of the mask.

The first insulating layer and the second insulating layer may be made of a same material.

The first absorption layer and the second absorption layer may be made of a same material.

In an embodiment, a deposition apparatus may include: a deposition chamber; and a mask assembly disposed in the deposition chamber, the mask assembly including: a mask, and a mask frame that supports the mask; and a deposition source that ejects a deposition material to the mask assembly, wherein the mask frame may include: a frame main body that supports the mask; an insulating layer that blocks energy from being transmitted to the frame main body; and an absorption layer that absorbs energy from external light, and the insulating layer may be disposed between a first surface of the frame main body and the absorption layer.

The frame main body may include a frame opening defined by an inner side surface perpendicular to the first surface, and the mask may be disposed in the frame opening.

The insulating layer may include a ceramic material.

A thickness of the absorption layer may be thinner than a thickness of the frame main body.

According to the mask frame and the mask assembly having the mask frame according to the disclosure, it is possible to rapidly and effectively remove residual organic materials during a cleaning process.

### BRIEF DESCRIPTION OF THE DRAWINGS

FIG. 1 illustrates a schematic cross-sectional view of deposition equipment.

FIG. 2 illustrates a schematic top plan view of a display panel formed using deposition equipment.

FIG. 3 illustrates a schematic cross-sectional view taken along line I-I′ of FIG. 2.

FIG. 4 illustrates an exploded schematic perspective view of an example of a mask assembly including a mask and a mask frame.

FIG. 5 illustrates a schematic cross-sectional view of the mask assembly of FIG. 4.

FIG. 6 illustrates an enlarged schematic view of an area A of FIG. 5.

FIG. 7 illustrates an enlarged schematic view of an area B of FIG. 5.

FIG. 8 illustrates a schematic cross-sectional view of a mask assembly according to an embodiment.

FIG. 9 illustrates an enlarged schematic view of an area A′ of FIG. 8.

FIG. 10 illustrates a schematic cross-sectional view of a mask assembly according to another embodiment.

FIG. 11 illustrates an enlarged schematic view of an area A″ of FIG. 10.

FIG. 12 illustrates a schematic cross-sectional view of a mask assembly according to another embodiment.

FIG. 13 illustrates a schematic cross-sectional view of a mask assembly according to another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

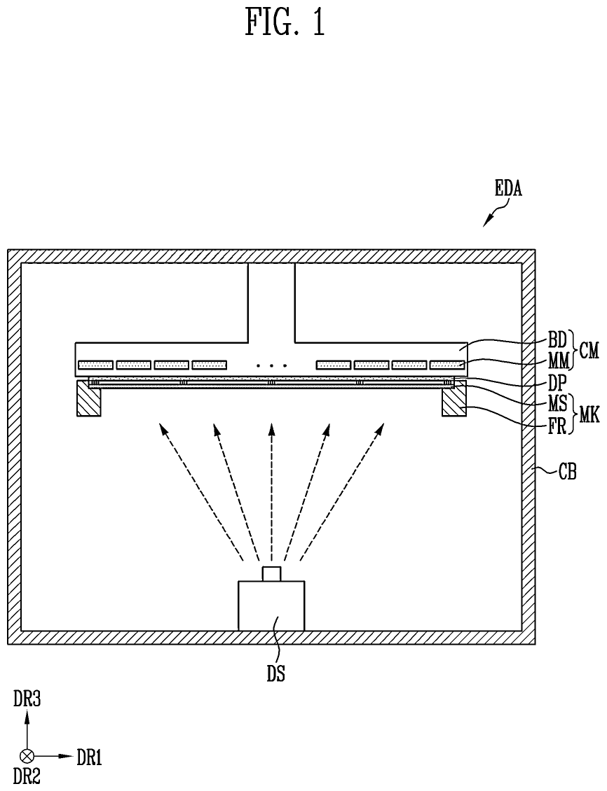

FIG. 1 illustrates a schematic cross-sectional view of deposition equipment.

Referring to FIG. 1, a deposition equipment (or deposition apparatus) EDA according to an embodiment may include a deposition chamber CB, a fixing member CM, a deposition source DS disposed inside the deposition chamber CB, and a mask assembly MK disposed inside the deposition chamber CB. For example, the deposition equipment EDA may further include an additional mechanical apparatus to implement an in-line system.

The deposition chamber CB may set a deposition condition to vacuum or may have a vacuum deposition condition. The deposition chamber CB may include a bottom surface, a ceiling surface, and side walls. The bottom surface of the deposition chamber CB may be parallel to a surface defined by a first direction DR1 and a second direction DR2. A normal direction of the bottom surface of the deposition chamber CB indicates a third direction DR3.

The fixing member CM may be disposed inside the deposition chamber CB, may be disposed on the deposition source DS, and may fix the mask assembly MK. The fixing member CM may be installed (or disposed) on the ceiling surface of the deposition chamber CB. The fixing member CM may include a jig or robot arm that holds the mask assembly MK.

The fixing member CM may include a support portion BD and magnetic materials MM coupled to the support portion BD. The support portion BD may include a plate as a basic structure for fixing the mask assembly MK, but embodiments are not limited thereto. The magnetic materials MM may be disposed inside or outside the support portion BD. The magnetic materials MM may fix the mask assembly MK with magnetic force.

The deposition source DS may evaporate the deposition material and eject it as deposition vapor. The deposition vapor may pass through the mask assembly MK and may be deposited on a display panel DP in a certain pattern. The display panel DP may be defined as a substrate in an intermediate step during a manufacturing process of a finished display panel DP to be described later.

The mask assembly MK may be disposed inside the deposition chamber CB, may be disposed on the deposition source DS, and may support the display panel DP. The display panel DP may include a glass substrate or plastic substrate. The display panel DP may include a polymer layer disposed on a base substrate.

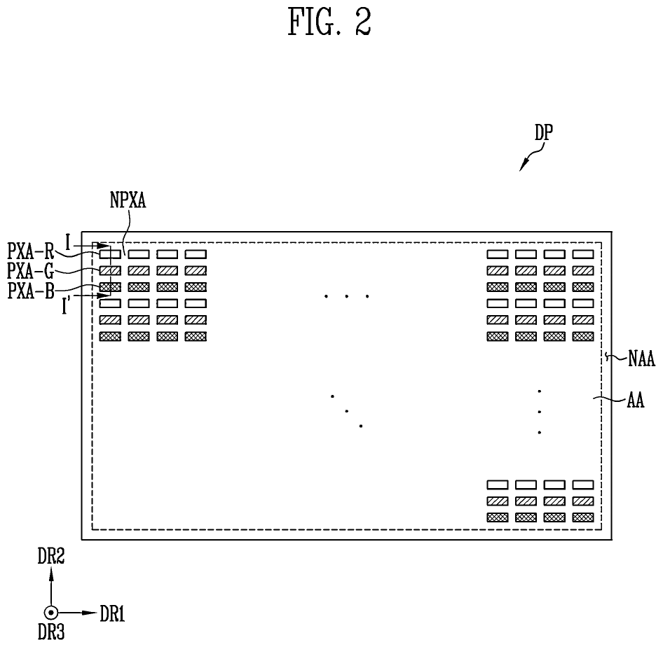

FIG. 2 illustrates a schematic top plan view of a display panel DP formed using a deposition equipment. FIG. 2 illustrates a schematic plan view of the display panel DP manufactured using the deposition equipment EDA (see FIG. 1). Display panels DP may be disposed on the mask assembly MK shown in FIG. 1 and a deposition process may be performed.

Referring to FIG. 2, the display panel DP according to an embodiment may include an active area AA and a peripheral area NAA. The display panel DP may include a first light emitting area PXA-R, a second light emitting area PXA-G, and a third light emitting area PXA-B that are distinct from each other within the active area AA. For example, the first light emitting area PXA-R may be a red light emitting area that emits red light, the second light emitting area PXA-G may be a blue light emitting area that emits green light, and the third light emitting area PXA-B may be a blue light-emitting area that emits blue light.

The first to third light emitting areas PXA-R, PXA-G, and PXA-B may be separated from each other, and may not overlap each other when viewed on a plane defined by the first direction DR1 and the second direction DR2, and an area between the adjacent light emitting areas PXA-R, PXA-G, and PXA-B may be defined as a non-light emitting area NPXA.

The display panel DP shown in FIG. 1 and FIG. 2 may include at least one functional layer manufactured using a mask MS. For example, among the functional layers included in the display panel DP, the functional layer in the form of a common layer provided to overlap all of the light emitting areas PXA-R, PXA-G, and PXA-B may be provided using the mask MS.

The light emitting areas PXA-R, PXA-G, and PXA-B of the display panel DP according to an embodiment may be arranged in a stripe shape. For example, first light emitting areas PXA-R, second light emitting areas PXA-G, and third light emitting areas PXA-B may be alternately arranged along the first direction DR1, and light emitting areas providing light of the same color may be arranged to be spaced apart from each other along the second direction DR2.

For example, the arrangement form of the light emitting areas PXA-R, PXA-G, and PXA-B is not limited thereto, and the order in which the first light emitting area PXA-R, the second light emitting area PXA-G, and the third light emitting area PXA-B are arranged may be provided in various combinations according to the characteristics of display quality required for the display panel DP.

For example, the light emitting areas PXA-R, PXA-G, and PXA-B may have a PENTILE™ structure in the form of a diamond arrangement. For example, the areas of the light emitting areas PXA-R, PXA-G, and PXA-B may also be different from each other, and the arrangement shape and the arrangement area may be variously adjusted or modified according to the characteristics of the display quality required for the display panel DP.

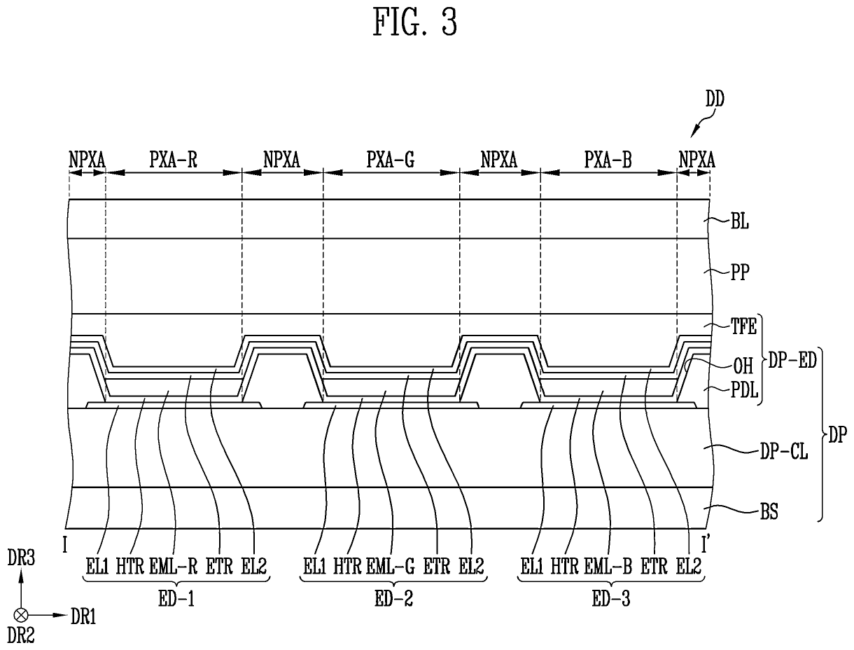

FIG. 3 illustrates a schematic cross-sectional view taken along line I-I′ of FIG. 2.

Referring to FIG. 3, the display panel DP formed using the deposition equipment EDA (see FIG. 1) may be combined with an optical layer PP and a cover substrate BL disposed on the display panel DP to form a display device DD. The display panel DP may include light emitting elements ED-1, ED-2, and ED-3. The optical layer PP may be disposed on the display panel DP to control reflected light from the display panel DP due to external light. The optical layer PP may include, for example, a polarizing layer or a color filter layer. For example, unlike shown in the drawing, the optical layer PP may be omitted in the display device DD of the embodiment.

The cover substrate BL may be disposed on the optical layer PP. The cover substrate BL may be a member that provides a base surface on which the optical layer PP is disposed. The cover substrate BL may be an inorganic layer, an organic layer, or a composite material layer. For example, unlike the illustration, the cover substrate BL may be omitted in the embodiment.

In an embodiment, the display panel DP may include a base layer BS, a circuit layer DP-CL provided on the base layer BS, and a display element layer DP-ED. The display element layer DP-ED may include the light emitting elements ED-1, ED-2, and ED-3. For example, the display panel DP may include an encapsulation layer TFE disposed on the display element layer DP-ED.

In an embodiment, the display panel DP may be an organic electroluminescence display panel including an organic electroluminescence element in the display element layer DP-ED. For example, the mask MS (refer to FIG. 1) may be used to form a portion of the functional layer of the display element layer DP-ED of the organic electroluminescence display panel.

In an embodiment, the circuit layer DP-CL may be disposed on the base layer BS, and the circuit layer DP-CL may include transistors. Each of the transistors (not shown) may include a control electrode, an input electrode, and an output electrode. For example, the circuit layer DP-CL may include insulating layers.

The encapsulation layer TFE may cover the light emitting elements ED-1, ED-2, and ED-3. The encapsulation layer TFE may seal the display element layer DP-ED. The encapsulation layer TFE may be a thin film encapsulation layer.

Each of the light emitting elements ED-1, ED-2, and ED-3 may include a first electrode EL1, a hole transport area HTR, light emitting layer EML-R, EML-G, and EML-B, an electron transport area ETR, and a second electrode EL2.

At least a portion of the first electrode EL1 of each of the light emitting elements ED-1, ED-2, and ED-3 may be exposed through the display opening OH defined in the pixel defining film PDL. The light emitting layers EML-R, EML-G, and EML-B may be disposed in the display opening OH, and the hole transport area HTR, the electron transport area ETR, and the second electrode EL2 may be provided as a common layer throughout the light emitting elements ED-1, ED-2, and ED-3.

At least one of the hole transport area HTR, the electron transport area ETR, and the second electrode EL2 provided as a common layer in the light emitting elements ED-1, ED-2, and ED-3 of the display panel DP may be provided using the mask MS.

For example, some of the insulating layers included in the circuit layer DP-CL or the encapsulation layer TFE disposed on the light emitting elements ED-1, ED-2, and ED-3 may also be provided using the mask MS.

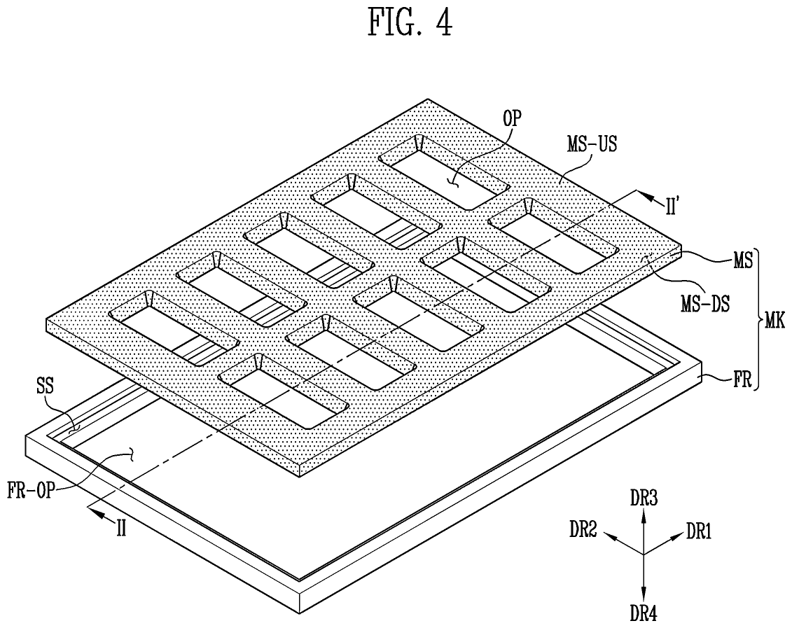

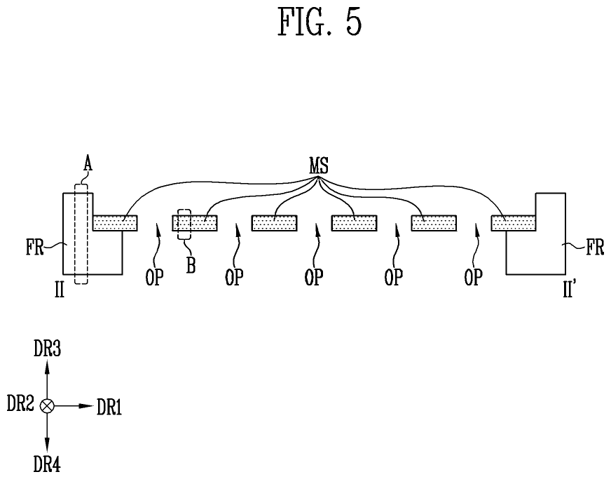

FIG. 4 illustrates an exploded schematic perspective view of an example of a mask assembly including a mask and a mask frame. FIG. 5 illustrates a schematic cross-sectional view of the mask assembly of FIG. 4. FIG. 5 illustrates a schematic cross-sectional view taken along line II-II′ in FIG. 4. In FIG. 4 and FIG. 5, a direction opposite to the first direction DR1 may be defined as a fourth direction DR4.

Referring to FIG. 4 and FIG. 5, the mask assembly MK may include a mask MS and a mask frame FR. In an embodiment, the mask assembly MK may be used to form a common layer including the same material on the target material, which is the deposition surface. In an embodiment, the mask assembly MK may include an open mask for thin film processing used to form a functional layer provided as a thin film. The open mask for thin film processing may be a mask used to stack thin film layers of the same material throughout each individual display device on a target substrate.

The mask frame FR may support the mask MS. For example, a frame opening FR-OP may be defined inside the mask frame FR, and the mask MS may be disposed within the frame opening FR-OP. For example, the mask frame FR may have an upper surface and a lower surface perpendicular to the third direction DR3. For example, the frame opening may be defined by inner side surfaces perpendicular to the upper surface. The inner side surfaces defining the frame opening may be perpendicular to the lower surface.

The mask frame FR may support the edge portion of the mask MS. In an embodiment, the mask frame FR may be disposed below the mask MS. The mask MS may be seated (or disposed) on the mask frame FR. For example, the mask frame FR may include a support surface SS supporting the mask MS inside where the frame opening FR-OP is defined, and the mask MS may be disposed on the support surface SS. However, embodiments are not limited thereto, and the mask frame FR may be disposed above and below the edge portions of the mask MS to support the mask MS.

For example, the mask MS may be fixed to the mask frame FR. The mask MS may be fixed to the mask frame FR by a method such as a welding process.

The mask frame FR may be made of a metal material including at least one of iron (Fe) and nickel (Ni). For example, the mask frame FR may include an alloy of iron and nickel. The mask frame FR may be manufactured to include stainless steel (SUS) or Invar.

The mask MS may include at least one open area OP. In an embodiment, the mask MS may include open areas OP that are spaced apart from each other in a plan view.

The open areas OP may be defined by being aligned on a plane defined by the first direction DR1 and the second direction DR2. FIG. 4 illustrates an embodiment of the mask MS in which five open areas OP are defined to be spaced apart from each other along the first direction DR1, and two open areas OP are defined to be spaced apart from each other along the second direction DR2. However, this is an example, and the number of the open areas OP is not limited to those illustrated. The open areas OP may be arranged at regular intervals (or distances) along one of the first direction DR1 and the second direction DR2. A material forming a functional layer in the form of a common layer through each of the open areas OP may be deposited on the target substrate.

The mask MS may be made of a metal material including at least one of iron (Fe) and nickel (Ni). For example, the mask MS may include an alloy of iron and nickel. The mask MS may be manufactured to include stainless steel (SUS) or Invar. The mask MS and the mask frame FR may be made of the same material. However, embodiments are not limited thereto.

The mask MS may have a thermal expansion coefficient of about 5 ppm/° C. or less. For example, the mask frame FR may also have a thermal expansion coefficient similar to that of the mask MS. Accordingly, thermal deformation of the mask MS during the deposition process may be minimized, thereby improving deposition quality on the target substrate.

The mask MS according to an embodiment may have a plate shape extending along the first and second directions DR1 and DR2. In an embodiment, the mask MS may have a quadrangular shape when viewed on a plane defined by the first and second directions DR1 and DR2. However, embodiments are not limited thereto, and the shape of the mask MS may be modified and provided in different forms according to the shape of the target substrate, which is the deposition surface, or the shape of the mask frame FR supporting the mask MS.

For example, the open areas OP in the mask MS of the embodiment may have a quadrangular shape in a plan view. However, embodiments are not limited thereto, and the shape of the open areas OP may be modified to have various shapes according to the shape of the functional layers deposited and formed on the target substrate.

The mask MS may include a lower surface (or first surface) MS-DS and an upper surface (or second surface) MS-US that face each other.

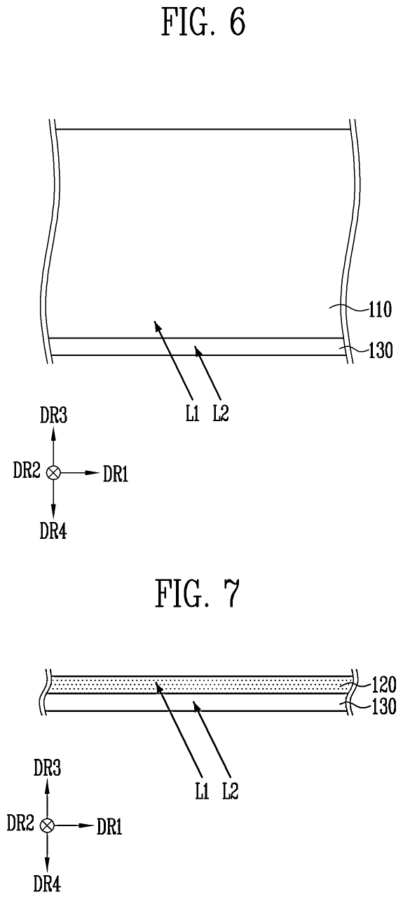

FIG. 6 illustrates an enlarged schematic view of an area A of FIG. 5.

After the deposition process of the display panel DP, the deposition material may remain on the mask frame FR. In FIG. 6, a residual layer 130 may be formed on a frame layer 110 based on the fourth direction DR4. The frame layer 110 may form the mask frame FR. The residual layer 130 may be a deposition material that remains on the frame layer 110 after the deposition process. As an example, the residual layer 130 may include an organic material.

In order to reuse the mask frame FR, the residual layer 130 may need to be removed on the frame layer 110. As a method for removing the residual layer 130, a method of irradiating high energy light onto the residual layer 130 may be used. In some embodiments, light generated from a xenon flash lamp may be irradiated onto the residual layer 130. For example, light generated from a xenon flash lamp may have a wavelength of about 200 nm to about 1200 nm. For example, the energy of light L2 having a wavelength of about 250 nm to about 430 nm may be absorbed into the residual layer 130. For example, the energy of light L1 in the remaining wavelength band may pass through the residual layer 130 to be transmitted to the frame layer 110.

The temperature of the residual layer 130 may increase by the light L2 having a wavelength of about 250 nm to about 430 nm. For example, the temperature of the frame layer 110 may increase by the light L1 in the remaining wavelength band. As the temperature of the residual layer 130 increases, the material forming the residual layer 130 may be vaporized and the residual layer 130 may be removed. For example, the mask frame cleaning process through light irradiation may be performed.

FIG. 7 illustrates an enlarged schematic view of an area B of FIG. 5.

After the deposition process of the display panel DP, the deposition material may remain on the mask MS. In FIG. 7, a residual layer 130 may be formed on a mask layer 120 based on the fourth direction DR4. The mask layer 120 may form the mask MS.

In order to reuse the mask MS, the residual layer 130 needs to be removed on the mask layer 120. For example, light having high energy may be irradiated onto the residual layer 130 in the method described with reference to FIG. 6.

Since the mask MS and the mask frame FR form the mask assembly MK, the process of removing the residual layer 130 on the mask layer 120 and the process of removing the residual layer 130 on the frame layer 110 may be simultaneously performed. For example, the residual layer 130 on the mask layer 120 and the frame layer 110 may be simultaneously removed by irradiating light generated by a xenon flash lamp onto the mask assembly MK based on the fourth direction DR4.

Referring to FIG. 6 and FIG. 7 together, a thickness of the frame layer 110 forming the mask frame FR may be relatively thicker than that of the mask layer 120 forming the mask MS. The temperature of the mask layer 120, which has a relatively thin thickness, may rapidly increase due to the energy of light L1. Accordingly, the temperature of the residual layer 130 on the mask layer 120 may also rapidly increase, and the residual layer 130 may be rapidly removed from the mask layer 120.

However, the relatively thick frame layer 110 may have a large heat capacity, so the temperature thereof may slowly increase in case that it receives energy from the light L1. This may be a factor that prevents the temperature of the residual layer 130 on the frame layer 110 from increasing. For example, the temperature of the residual layer 130 on the frame layer 110 may slowly increase, and the residual layer 130 may be slowly or incompletely removed from the frame layer 110.

The mask frame according to an embodiment may include a coating layer on the frame main body FRB. The coating layer may reduce or may prevent the energy of light irradiated during the cleaning process from being transmitted to the frame main body FRB, and may rapidly increase the temperature of the residual layer. Accordingly, the residual layer 130 on the mask frame may be rapidly and effectively removed during the cleaning process.

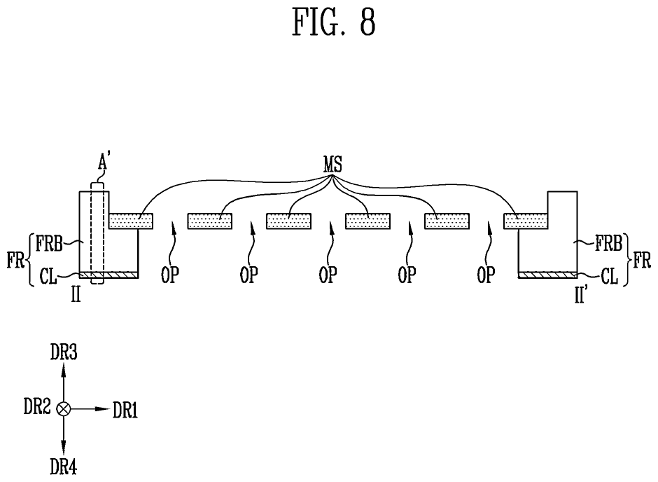

FIG. 8 illustrates a schematic cross-sectional view of a mask assembly according to an embodiment.

Referring to FIG. 8, the mask assembly may include a mask MS and a mask frame FR. The mask frame FR may include a frame main body FRB and a coating layer CL on the frame main body FRB. The mask assembly shown in FIG. 8 is the same as the mask assembly shown in FIG. 5, except that the mask frame FR includes the frame main body FRB and the coating layer CL on the frame main body FRB. Therefore, redundant descriptions thereof will be omitted below.

The frame main body FRB may be made of a metal material including at least one of iron (Fe) and nickel (Ni). For example, the frame main body FRB may include an alloy of iron and nickel. The frame main body FRB may be manufactured to include stainless steel (SUS) or Invar.

The coating layer CL may be formed on the frame main body FRB with respect to the fourth direction DR4. As described above with reference to FIG. 4, the mask frame FR may have upper and lower surfaces perpendicular to the third direction DR3, and the frame opening may be defined by side surfaces perpendicular to the upper surface. Likewise, the frame main body FRB may also have upper and lower surfaces perpendicular to the third direction DR3. In FIG. 8, the coating layer CL may be defined as being formed on an upper surface of the frame main body FRB based on the fourth direction DR4.

The coating layer CL may be formed to reduce or prevent the energy of light irradiated during the cleaning process from being transmitted to the frame main body FRB and to rapidly increase the temperature of the residual layer.

At least one of a plurality of layers included in the coating layer CL may be formed by a plasma spraying method. The coating material may be melted at a high temperature using thermal energy such as heating gas or electric discharge to generate molten particles, and may accelerate the generated molten particles through high-speed air and gas flows, and then by colliding it onto the base material, a film may be instantly formed on the surface of the base material.

In an embodiment, the coating layer CL may include an insulating layer and an absorption layer. The insulating layer may prevent or reduce light energy from being transmitted to the frame main body FRB. The absorption layer may absorb light energy and rapidly increase the temperature of the residual layer. For this purpose, the insulating layer may be interposed between the frame main body FRB and the absorption layer.

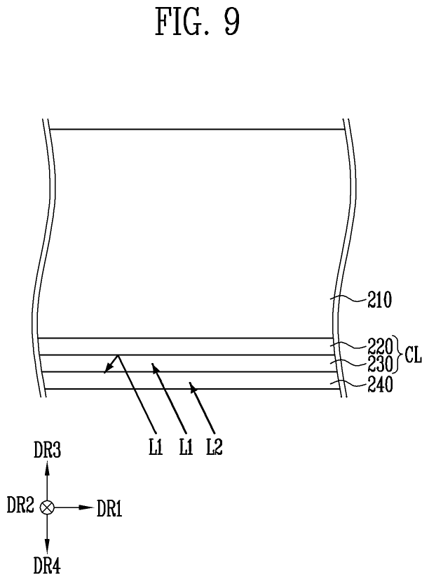

At least one of the insulating layer and the absorption layer included in the coating layer CL may be formed by a plasma spraying method. According to the plasma spraying method, the coating material may be melted at a high temperature using thermal energy such as heating gas or electric discharge to generate molten particles, and may accelerate the generated molten particles by high-speed air and gas flows, and then by colliding it onto the base material, a film may be instantly formed on the surface of the base material. However, this is only an example of a method of forming the coating layer CL, and the coating layer CL may be formed by another method. Hereinafter, it will be described in more detail with reference to FIG. 9.

FIG. 9 illustrates an enlarged schematic view of an area A′ of FIG. 8.

Referring to FIG. 9, the coating layer CL may be formed on a frame layer 210. The frame layer 210 may form the frame main body FRB. The frame layer 210 and the frame layer 110 shown in FIG. 6 may be made of substantially the same material.

For example, an insulating layer 220 and an absorption layer 230 may be sequentially formed on the frame layer 210 based on the fourth direction DR4. For example, the insulating layer 220 may be interposed between the frame layer 210 and the absorption layer 230 forming the frame main body FRB.

In FIG. 9, a residual layer 240 may be formed on the coating layer CL based on the fourth direction DR4. For example, the residual layer 240 may be formed on the absorption layer 230. The residual layer 240 of FIG. 9 and the residual layer 130 shown in FIG. 6 may be substantially the same material.

In order to reuse the mask frame FR, the residual layer 240 needs to be removed on the coating layer CL. For example, light generated from a xenon flash lamp may be irradiated onto the residual layer 240. For example, light generated from a xenon flash lamp may have a wavelength of about 200 nm to about 1,200 nm. For example, the energy of light L2 having a wavelength of about 250 nm to about 430 nm may be absorbed into the residual layer 240. For example, the energy of light L1 in the remaining wavelength band may pass through the residual layer 240 to be transmitted to the coating layer CL.

The temperature of the residual layer 240 may increase by the light L2 having a wavelength of about 250 nm to about 430 nm. For example, the temperature of the absorption layer 230 in the coating layer CL may increase by the light L1 in the remaining wavelength band. Since the absorption layer 230 is formed as a thin film whose thickness is much thinner than that of the frame layer 210, the temperature may quickly increase by absorbing the energy of the light L1. For example, the insulating layer 220 may reduce or prevent heat energy from the absorption layer 230 from being transmitted to the frame layer 210.

Through this, the energy of light generated from the xenon flash lamp may be used to increase the temperature of the absorption layer 230 and the residual layer 240, and may not be transmitted to the frame layer 210. Therefore, the residual layer 240 may be quickly and effectively removed during the cleaning process.

The insulating layer 220 may include a material to effectively block heat transmitted from the absorption layer 230 to the frame layer 210. According to an embodiment, the insulating layer 220 may include a ceramic material having good insulating properties. However, the insulating layer 220 is not limited thereto, and may include other materials.

The absorption layer 230 may include a material whose temperature rapidly increases by absorbing the energy of the light L1. According to an embodiment, the absorption layer 230 may be made of a metal material including at least one of iron (Fe) and nickel (Ni). For example, the absorption layer 230 may include an alloy of iron and nickel. As another example, the absorption layer 230 may be manufactured to include stainless steel (SUS) or Invar. In some embodiments, the absorption layer 230 and the frame layer 210 may be made of the same material.

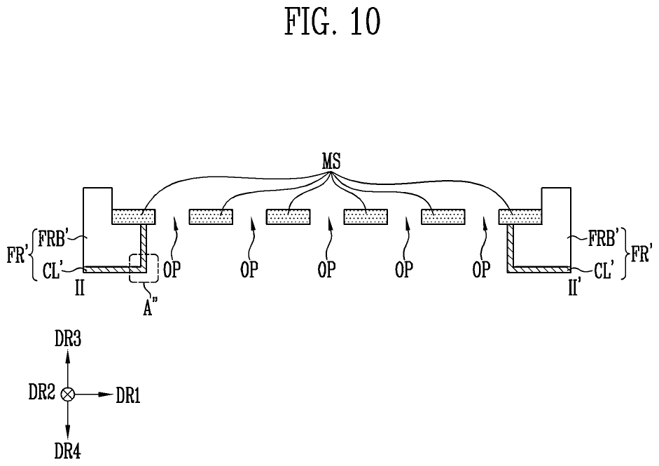

FIG. 10 illustrates a schematic cross-sectional view of a mask assembly according to another embodiment.

Referring to FIG. 10, the mask assembly may include a mask MS and a mask frame FR′. The mask frame FR′ may include a frame main body FRB′ and a coating layer CL′ on the frame main body FRB′. In the embodiment of FIG. 10, the coating layer CL′ may be formed not only on the upper surface but also on the inner side surface of the frame main body FRB′ based on the fourth direction DR4.

Similar to that described with reference to FIG. 8, the frame main body FRB′ of FIG. 10 may also have upper and lower surfaces perpendicular to the third direction DR3. In FIG. 10, the coating layer CL′ may be defined as being formed on an upper surface of the frame main body FRB′ based on the fourth direction DR4.

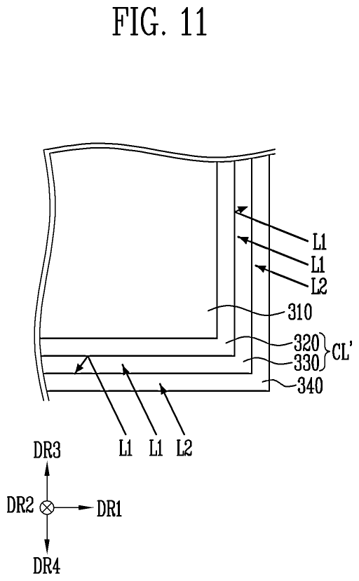

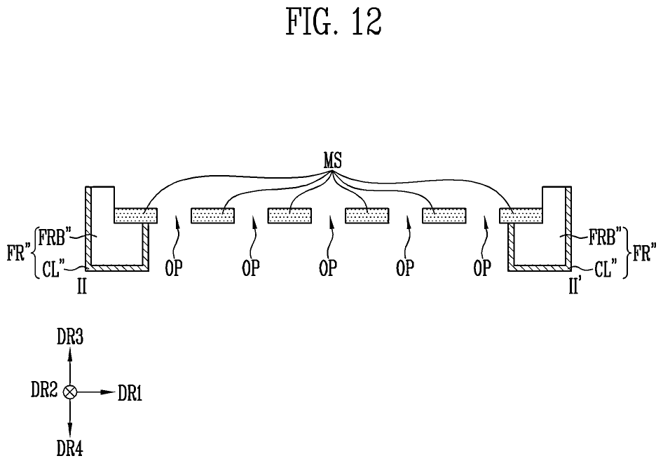

For example, the frame main body FRB′ may have a frame opening defined by inner side surfaces. Each of the inner side surfaces may be perpendicular to the upper surface of the frame main body FRB′. According to an embodiment shown in FIG. 10, the coating layer CL′ may also be formed on the inner side surface of the frame main body FRB′. Through this, the residual layer formed on the inner side surface of the frame main body FRB′ may be effectively removed. Hereinafter, it will be described with reference to FIG. 11.

FIG. 11 illustrates an enlarged schematic view of an area A″ of FIG. 10.

Referring to FIG. 11, the coating layer CL′ may be formed on the upper surface of a main body portion 310 in the fourth direction DR4 and the upper surface of the main body portion 310 in the first direction DR1. The main body portion 310 may form the frame main body FRB′.

For example, an insulating layer 320 and an absorption layer 330 may be sequentially formed on the main body portion 310 based on the fourth direction DR4. For example, the insulating layer 320 and the absorption layer 330 may be sequentially formed on the main body portion 310 based on the first direction DR1. For example, the insulating layer 320 may be interposed between the main body portion 310 and the absorption layer 330 forming the frame main body FRB′.

In FIG. 11, a residual layer 340 may be formed on the coating layer CL′ based on the first and fourth directions DR1 and DR4. For example, the residual layer 340 may be formed on the absorption layer 330.

Therefore, according to the embodiment of FIG. 11, not only residue formed on the upper surface of the mask frame FR′ based on the fourth direction DR4 but also residue formed on the inner side surface may be quickly and effectively removed during the cleaning process.

FIG. 12 illustrates a schematic cross-sectional view of a mask assembly according to another embodiment.

Referring to FIG. 12, the mask assembly may include a mask MS and a mask frame FR″. The mask frame FR″ may include a frame main body FRB″ and a coating layer CL″ on the frame main body FRB″. In the embodiment of FIG. 12, the coating layer CL″ may be formed not only on the upper and inner side surfaces of the frame main body FRB″ but also on the outer side surface of the frame main body FRB″ based on the fourth direction DR4. Through this, the residual layer formed on the outer side surface of the frame main body FRB″ may be rapidly and effectively removed.

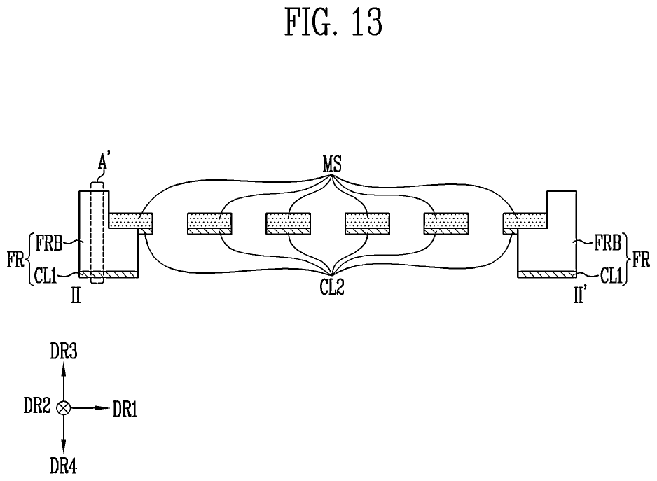

FIG. 13 illustrates a schematic cross-sectional view of a mask assembly according to another embodiment.

Referring to FIG. 13, the mask assembly may include a mask MS and a mask frame FR. The mask frame FR may include a frame main body FRB and a first coating layer CL1 on the frame main body FRB. The first coating layer CL1 may include a first insulating layer and a first absorption layer. For example, a second coating layer CL2 may be formed on the mask MS. The second coating layer may include a second insulating layer and a second absorption layer. Each of the first coating layer CL1 and the second coating layer CL2 may be formed in the same manner as the coating layer CL described with reference to FIG. 9. For example, the first insulating layer and the second insulating layer may be made of the same material, and the first absorption layer and the second absorption layer may also be made of the same material. For example, the thickness of the absorption layer included in the second coating layer may be thinner than the thickness of the mask MS. Therefore, according to the embodiment shown in FIG. 13, not only the residue formed on the first coating layer CL1 of the mask frame FR, but also the residue formed on the second coating layer CL2 of the mask MS may be rapidly and effectively removed.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A mask frame comprising:
a frame main body that supports a mask;
an insulating layer that blocks energy from being transmitted to the frame main body; and
an absorption layer that absorbs energy from external light, wherein
the insulating layer is disposed between a first surface of the frame main body and the absorption layer.

2. The mask frame of claim 1, wherein
the frame main body includes a frame opening defined by an inner side surface perpendicular to the first surface, and
the mask is disposed in the frame opening.

3. The mask frame of claim 1, wherein the insulating layer includes a ceramic material.

4. The mask frame of claim 1, wherein a thickness of the absorption layer is thinner than a thickness of the frame main body.

5. The mask frame of claim 1, wherein the absorption layer includes a metallic material.

6. The mask frame of claim 2, wherein the insulating layer is disposed between the absorption layer and the inner side surface defining the frame opening.

7. The mask frame of claim 1, wherein the insulating layer is disposed between an outer side surface of the frame main body and the absorption layer.

8. A mask assembly comprising:
a mask that forms a functional layer of a display device by a deposition process; and
a mask frame that supports the mask, wherein
the mask frame includes:
a frame main body that supports the mask;
a first insulating layer that blocks energy from being transmitted to the frame main body; and
a first absorption layer that absorbs energy from external light, and
the first insulating layer is disposed between a first surface of the frame main body and the first absorption layer.

9. The mask assembly of claim 8, further comprising:
a second insulating layer that blocks energy from being transmitted to the mask; and
a second absorption layer that absorbs energy from the external light,
wherein the second insulating layer is disposed between the mask and the second absorption layer.

10. The mask assembly of claim 8, wherein
the frame main body includes a frame opening defined by an inner side surface perpendicular to the first surface, and
the mask is disposed in the frame opening.

11. The mask assembly of claim 8, wherein the first insulating layer includes a ceramic material.

12. The mask assembly of claim 8, wherein a thickness of the first absorption layer is thinner than a thickness of the frame main body.

13. The mask assembly of claim 8, wherein the first absorption layer includes a metallic material.

14. The mask assembly of claim 9, wherein a thickness of the second absorption layer is thinner than a thickness of the mask.

15. The mask assembly of claim 9, wherein the first insulating layer and the second insulating layer are made of a same material.

16. The mask assembly of claim 9, wherein the first absorption layer and the second absorption layer are made of a same material.

17. A deposition apparatus comprising:
a deposition chamber; and
a mask assembly disposed in the deposition chamber, the mask assembly comprising:
a mask, and
a mask frame that supports the mask; and
a deposition source that ejects a deposition material to the mask assembly, wherein the mask frame includes:
a frame main body that supports the mask;
an insulating layer that blocks energy from being transmitted to the frame main body; and
an absorption layer that absorbs energy from external light, and
the insulating layer is disposed between a first surface of the frame main body and the absorption layer.

18. The deposition apparatus of claim 17, wherein
the frame main body includes a frame opening defined by an inner side surface perpendicular to the first surface, and
the mask is disposed in the frame opening.

19. The deposition apparatus of claim 17, wherein the insulating layer includes a ceramic material.

20. The deposition apparatus of claim 17, wherein a thickness of the absorption layer is thinner than a thickness of the frame main body.
